(19) United States
(12) Patent Application Publication
(10) Pub. No.: US 2003/0115517 A1
(43) Pub. Date: Jun. 19, 2003

(54) Microprocessor-based probe for integrated circuit testing

(76) Inventor: Ivo Wilhelmus Johaooes Marie Rutten, Saratoga, CA (US)

Correspondence Address: Corporate Patent Counsel, U.S. Philips Corporation, 580 White Plains Road, Tarrytown, NY, 10591, US

(21) Appl. No.: 10/023,537

(22) Filed: Dec. 18, 2001

(51) Int. Cl. G11C 29/00

(52) U.S. Cl. 714/718

(57) ABSTRACT

A test system is configured to include a programmable integrated circuit that is coupled between automatic test equipment (ATE) and a device-under-test (DUT). The programmable integrated circuit includes a microprocessor that is configured to accept relatively high-level test commands, typically in the form of a call to a pre-compiled subroutine or macro. Based on these high-level test commands, the microprocessor provides test stimuli to the device-under-test, collects test responses corresponding to these test stimuli, and provides raw or processed test responses to the ATE equipment for subsequent processing. Co-processors and other special purpose components are collocated with the microprocessor to further facilitate test-stimuli generation and test-response collection and processing via the programmable integrated circuit.

### BACKGROUND OF THE INVENTION

1. Field of the Invention

This invention relates to the field of integrated circuit technology, and in particular to the testing of integrated circuits.

2. Description of Related Art

The testing of integrated circuits, particularly at high frequency, is becoming increasingly more complex, and therefore more costly. Test equipment must be continually upgraded and enhanced to include capabilities for testing devices that typically include the latest state-of-the-art technology.

FIG. 1 illustrates an example test system 100 comprising automated test equipment (ATE) 110 that is coupled to a device-under-test (DUT) 150 via a probe card 140. The ATE 110 typically includes a set of core test components 120, and special purpose test modules 130. In the example of FIG. 1, the system 100 is configured to enable testing of high-speed multimedia devices, using, for example, special purpose audio and video modules in the set of test modules 130. If the system 100 is used to test communications devices, the set of test modules 130 may contain, for example, discrete Fourier transform (DFT) modules, and other modules particular to communications devices. As the technologies used in the development of new devices 150 are advanced, the test modules 130 must be upgraded to keep pace with these advancements.

As with any system, an ATE system 110 has limited resources. For example, an ATE system 110 has a limited number of input/output channels for communicating with the device-under-test 150. Additional channels can be costly, particularly if the channels are configured to operate at high speed. In like manner, an ATE system 110 has a limited amount of memory. Complex sequences of input test stimuli that are to be applied to the device 150, or complex sequences of expected test responses that are used for comparison with the actual test responses from the device 150, can consume a substantial amount of memory in the ATE system 110. Long sequences of test patterns often require a partitioning of the test patterns to fit in the available memory in the ATE system 110, which can add substantial time to the testing process. Also, common ATE systems 110 are single-processor systems that can only execute one instruction at a time. Providing a multiprocessor system that can simultaneously test multiple devices, or simultaneously perform complex tasks, would add substantially to the cost of an ATE system 110.

The testing of high-speed devices 150 via an ATE system 110 is particularly challenging. One of the particular problems associated with the testing of high-speed devices is the communication of signals to and from the device-under-test 150, particularly in the case of wafer-level testing. Long lead lines 111 from the test equipment 110 to the device-under-test 150 add capacitive and inductive loads to the driving signals. This additional load introduces a delay or mis-shaping of signals to and from the device-under-test 150. In many instances, certain tests cannot be performed ‘at device speed’, due to the distortions introduced by the long lead lines 111. Often, because the test system 100 is limited by the available test modules 130, the length of the leads 111, and other factors, tests are designed to correspond to the capabilities of the test system 100, rather than to the capabilities of the device-under-test 150. Additionally, because both the length and placement of the lines 111 affect the high-frequency characteristics of the lead lines 111, substantial time is often consumed with development and maintenance of the mechanical setup. During testing, substantial time is often consumed in determining whether an observed anomalous behavior is caused by a problem in the device-under-test 150, or a problem in the test setup.

Propagation delay and signal slew and skew caused by long lead lines also complicate the test development process. Commercial Automated Test Equipment (ATE) and other test systems generally allow a test engineer to develop test programs using a relatively high-level test programming language. Control loop structures, conditional branching, arithmetic functions, and the like are common in most, if not all, ATE test languages. The high-level test program is compiled to provide low-level code to the test modules 130, to effect the test program on a device-under-test 150. The compiler that is used to compile the high-level test program, however, is relatively unaware of the propagation effects caused by the long lead lines, and the compiled code is often unsuitable for testing devices at very high speed. Typically, a test engineer will prepare customized code for testing particular aspects of a device under test at maximum speed. This customized code may include, for example, particular ‘macros’ that are written in the low-level code used by the test modules 130. Alternatively, a limited subset of high-level code is used, to avoid particular control structures, arithmetic functions, and other features that result in the generation of substantial compiled code. This limited subset of high-level code effectively corresponds to the low-level code used by the test modules 130, but written in the format of the high-level language. That is, the advantages provided by the use of a high-level language for simplifying the task of preparing low-level code are often not realized when testing complex devices at high speed.

U.S. Pat. No. 5,793,117, “SEMICONDUCTOR DEVICE AND METHOD OF FABRICATING THE SAME”, issued Aug. 11, 1998, teaches an alternative technique where the test system 100 is replaced by a special purpose integrated circuit that is configured to directly contact bonding pads on the device-under-test 150, as illustrated in FIG. 2. This special purpose integrated circuit 201 includes “solder-bump” contacts 205 that are configured to contact corresponding contact pads 240 on the device-under-test 150.

As taught in the referenced patent, the probe card 140 is configured to effect the testing of the device-under-test 150, using test circuitry 202 in the integrated circuit 201, thereby eliminating the need for the test equipment 110 of FIG. 1. In accordance with this referenced patent, the special purpose integrated circuit 201 receives power 203 from an external source to power the test circuitry 202, and includes a light emitting diode (LED) that indicates whether the device-under-test 150 is defective. Because the test circuitry 202 is designed to be a stand-alone device that is capable of determining whether or not the device-under-test 150 is defective, without reliance upon the automatic test equipment 110 of FIG. 1, the design of the test circuitry 202 can be expected to be a complex and time consuming process. Additionally, because the test circuitry 202 is designed to test a particular device 150, the design and fabrication costs for the integrated circuit 201 cannot be allocated among a variety of devices. Additionally, because the test circuitry 202 is a designed as a hardware device that avoids the costs associated with ATE equipment, and a substantial portion of the cost of ATE equipment is associated with features provided to ease the test engineer's tasks, such as a high-level test language, the design of a test program or procedure to be performed by the circuitry 202 can be expected to be a tedious task. However, because the test circuitry 202 is designed to be in direct contact with the device-under-test 150, the aforementioned complexities caused by long lead lines are avoided.

### BRIEF SUMMARY OF THE INVENTION

It is an object of this invention to provide enhanced capabilities to an automated test equipment system without substantially adding to the cost of the ATE. It is a further object of this invention to provide a test system that minimizes the adverse affects caused by long lead lines between automated test equipment and a device-under-test. It is a further object of this invention to provide a test architecture that facilitates the testing of a variety of devices. It is a further object of this invention to provide a test architecture that facilitates the use of a high-level test language.

These objects and others are achieved by a test system that includes a programmable integrated circuit that is coupled between automatic test equipment (ATE) and a device-under-test (DUT). The programmable integrated circuit includes a microprocessor that is configured to accept relatively high-level test commands, typically in the form of a call to a pre-compiled subroutine or macro. Based on these high-level test commands, the microprocessor provides test stimuli to the device-under-test, collects test responses corresponding to these test stimuli, and provides raw or processed test responses to the ATE equipment for subsequent processing. Co-processors and other special purpose components are collocated with the microprocessor to further facilitate test-stimuli generation and test-response collection and processing via the programmable integrated circuit.

### BRIEF DESCRIPTION OF THE DRAWINGS

The invention is explained in further detail, and by way of example, with reference to the accompanying drawings wherein:

FIG. 1 illustrates an example block diagram of a prior art test system that includes automated test equipment.

FIG. 2 illustrates an example block diagram of a prior art test system that eliminates the need for automated test equipment.

FIG. 3 illustrates an example block diagram of a test system that includes a programmable integrated circuit for processing high-level test commands that are communicated between automated test equipment and a device-under-test in accordance with this invention.

FIG. 4 illustrates an example arrangement of a test fixture that includes a programmable integrated circuit that provides direct contact to a device-under-test in accordance with this invention.

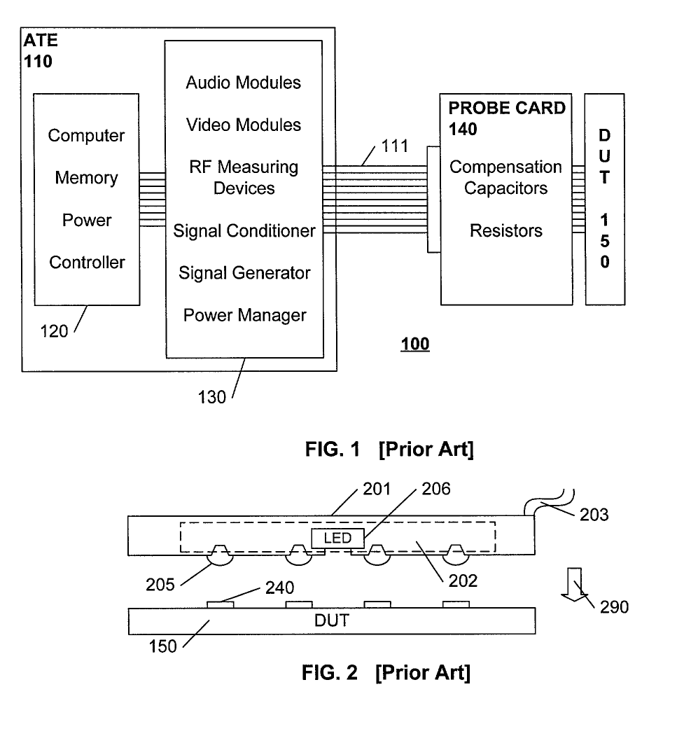

Throughout the drawings, the same reference numerals indicate similar or corresponding features or functions.

### DETAILED DESCRIPTION OF THE INVENTION

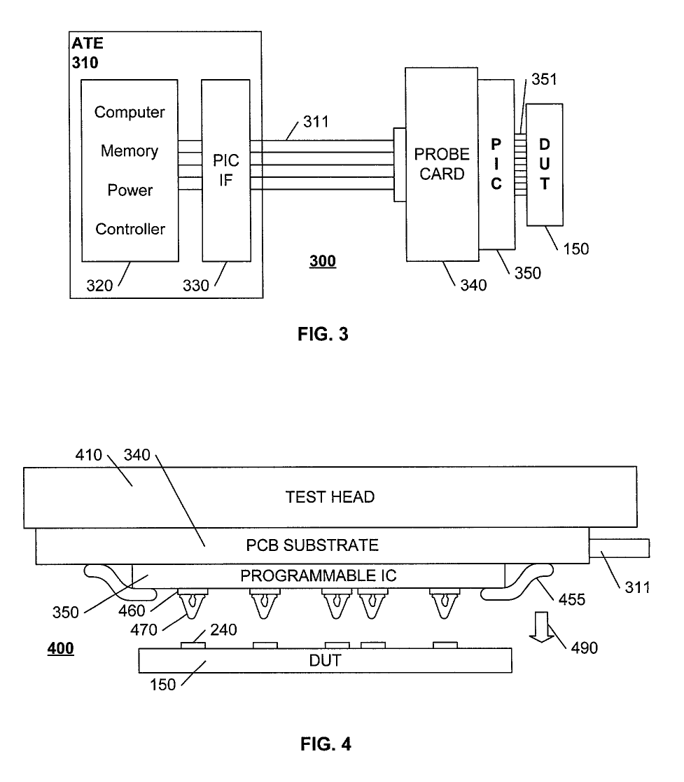

FIG. 3 illustrates an example block diagram of a test system that includes a programmable integrated circuit for processing high-level test commands that are communicated between automated test equipment and a device-under-test in accordance with this invention.

Consistent with conventional automated test equipment, the automated test equipment 310 includes a core system 320 that includes such items as a computer for generating a sequence of test operations, and a memory for storing a test program that controls the generation of the sequence of test operations, and for storing parameters related to the test operations, as well as the results obtained from the execution of the sequence of test operations. The core system 320 also preferably includes a power supply system that is configured to provide regulated voltage and currents to the device-under test 150, and other regulation and control systems as required.

The automated test equipment 310 also includes an interface 330 that is configured to facilitate the communication of signals to and from a programmable integrated circuit PIC 350, via lead lines 311. These signals include test signals and test commands that are transmitted from the automated test equipment 310, and test responses that are received from the programmable integrated circuit 350. In a preferred embodiment, the programmable integrated circuit 350 is mounted on a probe card 340 that facilitates the mechanical and electrical connection of the circuit 350 to the equipment 310.

In accordance with this invention, the programmable integrated circuit 350 is configured to communicate test-stimuli and to receive test-responses to and from the device-under-test 150, respectively, so as to minimize signal distortions or other anomalies caused by long lead lines 311 between the automated test equipment 310 and the device-under-test 150. Additionally, the programmable integrated circuit 350 is configured to provide the test-stimuli and to collect and process the test-responses based on test commands received from the automated test equipment 310. In this manner, the memory resources and channel bandwidth required at the automated test equipment can be minimized. That is, in a conventional ATE test setup, the ATE provides the test-stimuli or receives the test-responses directly to and from a device-under-test 150. The signals that are propagated from the ATE are the actual signals that are applied to the device-under-test 150. In accordance with this invention, however, in addition to, or in lieu of, the conventional test signals, the ATE is configured to communicate test commands, from which the programmable integrated circuit 350 develops some or all of the actual test signals that are applied to the device-under-test 150. Because the test commands can be expected to be communicated with less channel bandwidth than the actual set of test signals, less memory and fewer channels are required at the ATE 110.

Consider a simple example of measuring the “set-up” time of a register. The set-up time is defined as the time that the data-input to the register must be available, relative to the active edge of the clock. If the data-input arrives after the set-up time, it will not be reliably loaded into the register. This simple example is provided for ease of understanding. One of ordinary skill in the art will recognize by this example, however, that the principles of this invention are particularly well suited to the complex testing of actual devices and systems.

An example subroutine that tests for set-up time follows.

Sub SetupTest (Register, A, B, min, max, increment)

Initialize hold to default_hold
For setup = max to min, step -increment

Initialize Register[Value] to A
Clear Register[Clock]
Set Register[Data-input] to B
Wait (setup)
Trigger Register[Clock]
Wait (hold)
Get Register[Output]
If (Register[Output]<>B) then return (setup+increment)

Next set-up
return (min)

Sub End

The core of the subroutine resets the register to a value of A, then sets the data-input to a value of B, waits for a given setup time, then applies the clock to write the data-input into the register. After a hold time, it reads the output, which should be the same as the data-input, if the data-input has been properly written into the register. This core is placed within a loop that sets the given setup time at set increments between a maximum and minimum value. If, at any given setup time, the output differs from the data-input, then the given setup time must have been insufficient, and the subroutine returns a value of the prior setup time (setup+increment). If the entire range of setup times is sufficient to allow the data-input to be written into the register, the subroutine returns the minimum setup time tested.

One of ordinary skill in the art will recognize that the communication of a call to the above subroutine, with the six arguments of the subroutine, will consume less bandwidth than the communication of each initialization set of signal values and each trigger value for each cycle through the core loop.

One of ordinary skill in the art will also recognize that the measured set-up time in the above subroutine actually corresponds to the setup time of the register plus or minus any differences in propagation time between the data-input signal line and the clock signal line. That is, there will be a finite data propagation delay time between the time that the “Set Register[Data-input] to B” command is executed and the time that the value B is actually present at the Data-input probe point of the device-under-test. And, there will be a finite clock propagation delay time between the time that the “Trigger Register[Clock]” command is executed and the time that the active edge of the clock is actually present at the Clock probe point of the device-under-test. If the data propagation delay time is longer than the clock propagation delay time, the reported setup time will be longer than the actual register setup time; if the clock propagation delay time is longer than the data propagation delay time, the reported setup time will be shorter than the actual register setup time.

If the above subroutine is executed at a conventional ATE, the propagation delay time of the signal lines are likely to differ, albeit to a small extent. When measuring high-speed performance, however, this “small extent” often becomes significant. To properly measure high-speed performance, the individual signals' propagation delay must be measured, and the test program must be suitably adjusted to compensate for any differences. If, on the other hand, the above subroutine is executed at the programmable integrated circuit 350 of FIG. 3 that is proximate to the device-under test 150, the propagation delay times, even at high-speeds, of the signal lines become substantially insignificant, or at least comparable to the propagation delay times that will be experienced when the device 150 is mounted on a printed circuit in a product, and no modifications or adjustments to the test program need to be made to properly test the device.

One of ordinary skill in the art will recognize that more substantial problems can arise when testing for other parameters or functions in a complex electronic circuit. For example, measuring a time or phase delay between an applied stimuli and a response to the stimuli requires an accurate determination of the propagation delay time of the stimuli to the device-under-test, and the propagation delay time of the response from the device-under-test, particularly if these propagation delays are of a similar order of magnitude to the time or phase delay being measured. By providing a subroutine at the programmable integrated circuit 350 that applies the stimuli and measures the time duration until the response is observed, the propagation delays will be minimized, and in most instances, can be ignored.

In a preferred embodiment of this invention, one or more subroutines are downloaded to the programmable integrated circuit 350. For the purposes of this invention, the term subroutine is used in its broadest sense to mean a sequence of operations that can be selectively invoked, and includes ‘macros’, ‘threads’, ‘agents’, ‘subprocesses’, ‘objects’, and so on. The subroutines may include subroutines from a library of common test processes, or subroutines that are specifically in designed for a particular device-under-test 150, or subroutines for a particular class of devices, or any combination thereof. The test program language for the ATE will include high-level test commands that, when executed, cause a corresponding subroutine at the programmable integrated circuit 350 to perform its task. The test program language may be configured to include, for example, a “CALLPIC Subname (Args)” command that causes the programmable integrated circuit 350 to execute the indicated subroutine with the arguments provides. For example, using the above example subroutine, the test program may include:

CALL SetupTest (Reg7, 0, 1, 2, 10, 0.5),

which causes the programmable circuit 350 to execute the above example subroutine for the register that is referred to as Reg7. (Other high level commands facilitate the mapping of component names to particular signals, or pins, on the device-under-test). When this call is executed, it will cause the circuit 350 to test the setup time for changing the value in Reg7 from a logic-0 to a logic-1 for setup times between 10 and 2 time units, at increments of −0.5, and will return the minimum tested setup time (2) if all tests are successful, or the last good setup time, if the tests fail at some point. As will be evident to one of ordinary skill in the art, the availability of this higher level ‘call’ to a process that is executed in proximity to the device-under-test eliminates the need to be concerned with the delays introduced on the test signals, nor with the delays introduced by the processing of the call command. Additionally, the availability of this higher level ‘call’ will generally provide for a more efficient utilization of available channel bandwidth between the ATE and the test probe.

One or ordinary skill in the art will also recognize that if, according to this invention, the subroutine is executed at the programmable integrated circuit 350, the ATE 310 is free to perform other tasks while waiting for the returned value from the setup time test from the programmable integrated circuit 350. In particular, if the probe card 340 is configured to contain multiple programmable integrated circuits 350, for simultaneously testing multiple devices-under-test 150, the ATE 310 could merely initiate the setup time test subroutine at each circuit 350, sequentially or simultaneously, then collect the returned setup time results from each circuit 350 as the individual tests are completed. In this manner, the single-processor ATE 310 can effectively perform a series of simultaneous tasks by delegating the tasks among one or more programmable integrated circuits 350. In like manner, the effective memory space available for testing is increased, because the programmable integrated circuit 350 will contain a memory, for storing the test commands, parameters, and the like, as well as storing intermediate test results prior to formulating a response to the ATE 310.

Of particular note, the programmable integrated circuit 350 of this invention is particularly well suited for the testing of memory devices. Typically, a memory device is tested by writing specific values into each memory location, and subsequently reading the values from each memory location, to verify the writing operation. Particular patterns, such as ‘checker-board’ patterns, are often used to test for certain sensitivities of particular memory structures or technologies to errors. Such testing is typically a time consuming process, particularly for large sized memories, but relatively trivial in complexity, and can be easily programmed into a relatively simple, and therefore low-cost, programmable integrated circuit 350.

FIG. 4 illustrates an example arrangement of a test fixture 400 that includes a programmable integrated circuit 350 that provides direct contact to a device-under-test 150 in accordance with this invention. In a preferred embodiment, the text fixture 400 includes a test head 410, upon which is mounted a printed circuit board substrate that forms the probe board 340. The probe board 340 provides communication between the automated test equipment and the programmable integrated circuit 350, via conductors 311 and 455. The probe board 340 is illustrated in FIG. 4 as containing a single programmable integrated circuit 350, although, as noted above, it may containing multiple programmable integrated circuits 350 for simultaneously testing a plurality of devices-under-test 150, as well as other components that facilitate the testing of one or more devices-under-test 150. Copending U.S. patent application, “PRECONDITIONING INTEGRATED CIRCUIT FOR INTEGRATED CIRCUIT TESTING”, Ser. No., filed Nov. 8, 2001, for Ivo Rutten, Attorney Docket US018179, teaches the use of pre-conditioning circuits on a test IC that in direct contact with a device-under-test, and is incorporated by reference herein. In this copending application, devices such as filters, converters, comparators, and so on, are used to condition signals before they are presented to the device-under-test, and to condition or process signals from the device-under-test before the results are communicated to the ATE. As incorporated into this invention, the programmable component of the programmable integrated circuit 350 would be configured to control some of all of these conditioning or processing components to further enhance the programmable capabilities of the programmable integrated circuit 350.

As in the above referenced copending application, in a preferred embodiment of this invention, the programmable integrated circuit 350 includes a plurality of contact points 470 that are configured to provide direct contact with corresponding contact points 240 on the device-under-test. Alternatively, the test contacts 470 may be located elsewhere on the probe board 340, and coupled to the programmable integrated circuit 350 as required. Because the programmable integrated circuit 350 is located on the test head 410, and the test head 410 is designed to provide direct contact with the device-under-test 150, adverse affects caused by the propagation of signals to and from a relatively remote automated test equipment 310 (of FIG. 3) via lead lines 311 can be minimized.

Any of a variety of techniques may be used to provide the contact points 470. Conventional techniques include the use of microsprings, as well as the solder bumps of the aforementioned U.S. Pat. No. 5,793,117. In a preferred embodiment, the contact points 470 are affixed to bonding pads 460 on the programmable integrated circuit 350, as discussed further below. Copending U.S. patent application “CHIP-MOUNTED CONTACT SPRINGS”, Ser. No. ______ filed Nov. 8, 2001 for Ivo Rutten, Attorney Docket US018180, teaches a contact technology that is particularly well suited for use in this invention, and is incorporated by reference herein. This copending application teaches the bonding of a segment of bonding wire to two adjacent points, forming a “V-shaped” contact point, the vertex of the “V” forming the contact point for contacting a corresponding contact 240 of the device-under-test 150, as illustrated in FIG. 4. The dual-bonded V-shaped contact 240 provides an inherently stable and resilient structure for repeated tests of devices 150, via a movement 490 of the test head 410 relative to each device-under-test 150.

The foregoing merely illustrates the principles of the invention. It will thus be appreciated that those skilled in the art will be able to devise various arrangements which, although not explicitly described or shown herein, embody the principles of the invention and are thus within its spirit and scope. For example, many complex digital circuits include “built-in-self-test” (BIST) capabilities, wherein the ATE activates a certain set of inputs and the device-under-test, or parts of the device-under-test, enter a self-test mode. Upon completion of the test, the device-under-test returns the results of the test, often as a “pass” or “fail” signal. As with this invention, the BIST features of a device-under-test allows the device to perform tests without regard to the propagation delays of the connections to the ATE, and frees the ATE to perform other tasks while the self-test is being performed. The BIST features, however, consume area on each device-under-test, and add to the production cost, and failure rate, of the devices. In view of this disclosure, one or ordinary skill in the art will recognize that some, or all, of the BIST capabilities of a device may be embodied in the programmable integrated circuit 350. In this manner, the advantages of BIST can be realized, via the programmable integrated circuit 350, without consuming area on the production devices. These and other system configuration and optimization features will be evident to one of ordinary skill in the art in view of this disclosure, and are included within the scope of the following claims.

I claim:

1. A test system comprising:
automated test equipment that includes:
a computer that is configured to execute a sequence of test operations for testing a device-under-test, and
an interface circuit, operably coupled to the computer, that is configured to transmit at least one test command of the sequence of test operations, and
a programmable integrated circuit, operably coupled to the automated test equipment and in immediate proximity to the device-under-test, that is configured to receive the test command, and to generate therefrom at least one test signal that is communicated to the device-under-test, based on a programmed set of instructions corresponding to the test command.

2. The test system of claim 1, wherein
the programmable integrated circuit includes at least one contact point that is arranged to provide direct contact to the device-under-test for communicating the at least one test signal to the device-under-test.

3. The test system of claim 2, wherein
the at least one contact point includes a bonding pad upon which a resilient structure is bonded to facilitate the direct contact to the device-under-test.

4. The test system of claim 3, wherein
the resilient structure includes a bonding wire that is bonded to two substantially adjacent points on the programmable integrated circuit.

5. The test system of claim 1, wherein
the automated test equipment is also configured to receive at least one test response from the device-under-test, and
the programmable integrated circuit is also configured to receive a response signal from the device-under-test, and to generate therefrom the at least one test response for communication to the automated test equipment, also based on the programmed set of instructions corresponding to the test command.

6. The test system of claim 1, further including
a probe card, upon which the programmable integrated circuit is mounted, that facilitates coupling of the programmable integrated circuit to the automated test equipment.

7. The test system of claim 6, wherein
the probe card is configured to provide for the mounting of a plurality of programmable integrated circuits, thereby facilitating simultaneous testing of a plurality of devices-under-test.

8. The test system of claim 1, wherein
the interface circuit is configured to use a first bandwidth to transmit the at least one test command to the programmable integrated circuit, and
the programmable integrated circuit is configured to use a second bandwidth that is larger than the first bandwidth to communicate the at least one test signal to the device-under-test.

9. The test system of claim 1, wherein
the device-under-test includes a memory device.

10. The test system of claim 1, wherein
the at least one test command is a subroutine call, and
the programmable integrated circuit is configured to generate the at least one test signal by executing a subroutine corresponding to the subroutine call.

11. An integrated circuit for testing a device-under-test comprising:
a programmable component that is configured to receive test commands from a test system, and to provide therefrom test signals, based on a programmed set of instructions, and
a plurality of contact points that are arranged to provide direct contact with the device-under-test for communicating the test signals to the device-under-test.

12. The integrated circuit of claim 11, wherein
each of the plurality of contact points includes a bonding pad upon which a resilient structure is bonded to facilitate a direct contact to the device-under-test.

13. The integrated circuit of claim 12, wherein
the resilient structure includes a bonding wire that is bonded to two substantially adjacent points on the programmable integrated circuit.

14. The integrated circuit of claim 11, further including
other components that are configured to condition the test signals prior to communicating the signals to the device-under-test.

15. The integrated circuit of claim 11, wherein
the programmable component is further configured to receive a response signal from the device-under-test, and to generate therefrom the at least one test response for communication to the test system, also based on the programmed set of instructions corresponding to the test commands.

16. The integrated circuit of claim 15, further including
other components that are configured to process the response signal prior to communicating the response signal to the programmable component.

17. A method of testing, comprising:
programming an automated test equipment to execute a sequence of test operations for testing a device-under-test via a transmission of at least one test command to a programmable integrated circuit,
programming the programmable integrated circuit to receive the test command, and to generate therefrom at least one test signal, and
placing the programmable integrated circuit in proximity to the device-under-test, to provide a direct communication of the test signal to the device-under-test.

18. The method of claim 17, further including
programming other programmable integrated circuits to receive the test command, and to generate therefrom at least one corresponding test signal, and
placing the other programmable integrated circuits in proximity to the other devices-under-test, to provide a direct communication of the corresponding test signal to the other devices-under-test, thereby facilitating simultaneous testing of the devices-under-test.
